(19) United States
(12) Patent Application Publication
(10) Pub. No.: US 2026/0090156 A1
(43) Pub. Date: Mar. 26, 2026

(54) LIGHT-EMITTING STRUCTURE

(71) Applicant: GUANGZHOU LUXVISIONS INNOVATION TECHNOLOGY LIMITED, Guangzhou City (CN)

(72) Inventors: Lee Lin Tsai, Guangzhou City (CN); Wei-Han Wu, Guangzhou City (CN)

(73) Assignee: GUANGZHOU LUXVISIONS INNOVATION TECHNOLOGY LIMITED, Guangzhou City (CN)

(21) Appl. No.: 19/185,267

(22) Filed: Apr. 22, 2025

Related U.S. Application Data
(60) Provisional application No. 63/699,765, filed on Sep. 26, 2024.

(30) Foreign Application Priority Data
Jan. 9, 2025 (CN) 202510037138.7

(51) Int. Cl. H10H 20/856; H10H 20/80; H10H 20/841; H10H 20/851; H10H 20/854

(52) U.S. Cl. CPC H10H 20/856; H10H 20/841; H10H 20/8515; H10H 20/854; H10H 20/882

(57) ABSTRACT

This disclosure provides a light-emitting structure, including a substrate, at least one light-emitting chip, a reflective layer, an encapsulant, a reflective polarizer, and a polarization conversion element. The light-emitting chip is disposed on the substrate, and the reflective layer is disposed on the substrate. The encapsulant encapsulates the light-emitting chip, and covers the reflective layer. The reflective polarizer is disposed on the encapsulant, and the polarization conversion element is disposed on the encapsulant or within the encapsulant. The reflective polarizer is used to transmit the light having a first polarization direction from the light emitted by the light-emitting chip, and to reflect the light having a second polarization direction from the light, and the polarization conversion element is used to modify the polarization direction of the light reflected by the reflective polarizer.

### CROSS-REFERENCE TO RELATED APPLICATION

This application claims the priority benefits of U.S. provisional application Ser. No. 63/699,765, filed on Sep. 26, 2024 and China application serial no. 202510037138.7, filed on Jan. 9, 2025. The entirety of each of the above-mentioned patent applications is hereby incorporated by reference herein and made a part of this specification.

### BACKGROUND

### Technical Field

This disclosure relates to a light-emitting structure.

### Description of Related Art

In the prior art, the method of generating polarized light source is to use absorptive polarizers or absorptive polarization films to produce linearly polarized light, which is done by directly adding an absorptive polarizer or absorptive polarization film in front of a unpolarized light source to filter the light into linearly polarized light. However, this method will result in the loss of half of the light energy.

In addition, an optical distance for light mixing is required for producing uniform polarized light and it is difficult to achieve a thin type light source device, and the overall light source device tends to be bulky.

### SUMMARY

The disclosure is directed to a light-emitting structure, which possesses higher optical efficiency, and may feature the advantages of thinness and light weight.

An embodiment of the disclosure proposes a light-emitting structure, including a substrate, at least one light-emitting chip, a reflective layer, an encapsulant, a reflective polarizer, and a polarization conversion element. The light-emitting chip is disposed on the substrate, and the reflective layer is disposed on the substrate. The encapsulant encapsulates the light-emitting chip and covers the reflective layer. The reflective polarizer is disposed on the encapsulant, and the polarization conversion element is disposed on or within the encapsulant. The reflective polarizer is configured to transmit the light having a first polarization direction from the light emitted by the light-emitting chip, and to reflect the light having a second polarization direction from the light emitted by the light-emitting chip, and the polarization conversion element is configured to modify the polarization direction of the light reflected by the reflective polarizer.

An embodiment of the disclosure proposes a light-emitting structure, including a light guide plate, at least one light-emitting element, a light-transmitting layer, a reflective polarizer, and a first reflective layer. The light guide plate has a first surface, a second surface opposite to the first surface, and at least one light incident surface connecting the first surface and the second surface. The second surface is equipped with a light scattering microstructure layer. At least one light-emitting element is disposed next to the at least one light incident surface, and emits light towards the at least one light incident surface. The light-transmitting layer is disposed on the first surface. A refractive index of the light-transmitting layer falls below a refractive index of the light guide plate. The light-transmitting layer is disposed between the light guide plate and the reflective polarizer. The first reflective layer is disposed on the second surface.

In the light-emitting structure of the embodiment of this disclosure, a reflective polarizer is utilized to transmit the light having a first polarization direction from the light emitted by the light-emitting chip, and reflect the light having a second polarization direction from the light emitted by the light-emitting chip, and a polarization conversion element is adopted to modify the polarization direction of the light reflected by the reflective polarizer, so that more light possesses the first polarization direction and can transmit through the reflective polarizer. Therefore, the light-emitting structure of the embodiment of this disclosure may possess higher optical transmission efficiency. In addition, in the light-emitting structure of the embodiment of this disclosure, the reflective polarizer is disposed on the encapsulant, thus the light-emitting structure may be thin and possess light weight. In the light-emitting structure of the embodiment of this disclosure, the light-transmitting layer is configured on the first surface of the light guide plate, the light-transmitting layer is disposed between the light guide plate and the reflective polarizer, and the second surface of the light guide plate is equipped with a light scattering microstructure layer, therefore the polarization direction of the light reflected by the reflective polarizer may be modified through the light being scattered by the light scattering microstructure layer, thereby increasing the proportion of light passing through the reflective polarizer. Therefore, the light-emitting structure of the embodiment of this disclosure may possess higher optical transmission efficiency. Additionally, in the light-emitting structure of the embodiment of this disclosure, an architecture where the reflective polarizer is disposed above the first surface of the light guide plate is adopted, thus the light-emitting structure may be thin type and possess light weight.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic diagram of a light-emitting structure according to an embodiment of this disclosure.

FIG. 2 is a cross-sectional schematic diagram of a light-emitting structure according to another embodiment of this disclosure.

FIG. 3A is a top view schematic diagram of a light-emitting structure according to yet another embodiment of this disclosure.

FIG. 3B is a cross-sectional schematic diagram of the light-emitting structure of FIG. 3A.

FIG. 4 is a cross-sectional schematic diagram of a light-emitting structure according to still another embodiment of this disclosure.

FIG. 5 is a cross-sectional schematic diagram of a light-emitting structure according to another embodiment of this disclosure.

FIG. 6 is a cross-sectional schematic diagram of a light-emitting structure according to yet another embodiment of this disclosure.

FIG. 7 is a cross-sectional schematic diagram of a light-emitting structure according to still another embodiment of this disclosure.

FIG. 8A is a top view schematic diagram of a light-emitting structure according to another embodiment of this disclosure.

FIG. 8B is a side view schematic diagram of the light-emitting structure of FIG. 8A.

FIG. 9 is a cross-sectional schematic diagram of a light-emitting structure according to yet another embodiment of this disclosure.

FIG. 10 is a cross-sectional schematic diagram of a light-emitting structure according to still another embodiment of this disclosure.

FIG. 11 is a cross-sectional schematic diagram of a light-emitting structure according to another embodiment of this disclosure.

FIG. 12 is a cross-sectional schematic diagram of a light-emitting structure according to yet another embodiment of this disclosure.

### DESCRIPTION OF THE EMBODIMENTS

Now, exemplary embodiments of this disclosure will be referred to in detail, with examples of the exemplary embodiments illustrated in the accompanying drawings. Wherever possible, the same reference numerals in the drawings and description are used to denote the same or similar parts.

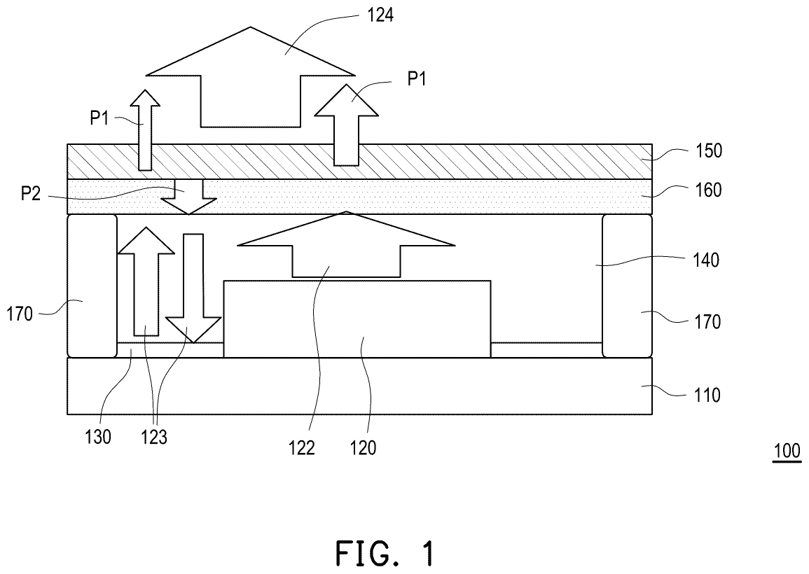

FIG. 1 is a cross-sectional schematic diagram of a light-emitting structure according to an embodiment of this disclosure. Referring to FIG. 1, a light-emitting structure 100 of this embodiment includes a substrate 110, at least one light-emitting chip 120 (in FIG. 1, one light-emitting chip is exemplified), a reflective layer 130, an encapsulant 140, a reflective polarizer 150, and a polarization conversion element 160. The light-emitting chip 120 is disposed on the substrate 110, and the reflective layer 130 is disposed on the substrate 110. The encapsulant 140 encapsulates the light-emitting chip 120 and covers the reflective layer 130. In this embodiment, the light-emitting chip 120 is exemplified as a light-emitting diode, such as a white light-emitting diode, a blue light-emitting diode, a red light-emitting diode, a green light-emitting diode, or a light-emitting diode with other colors.

The reflective polarizer 150 is disposed on the encapsulant 140, and the polarization conversion element 160 is disposed on the encapsulant 140 or within the encapsulant 140, and in this embodiment, the polarization conversion element 160 is disposed on the encapsulant 140, and the polarization conversion element 160 is exemplified as a light diffusion layer, disposed between the encapsulant 140 and the reflective polarizer 150.

The reflective polarizer 150 is used to transmit light P1 having a first polarization direction from the light 122 emitted by the light-emitting chip 120, and to reflect light P2 having a second polarization direction from the light 122, and the polarization conversion element 160 is used to modify the polarization direction of the light P2 reflected by the reflective polarizer 150. Specifically, although the light P2 reflected by the reflective polarizer 150 possesses the second polarization direction, its linear polarization characteristic of the second polarization direction will be disrupted by the diffusion effect of the light diffusion layer (i.e., the polarization conversion element 160), and converted into unpolarized light 123. As a result, the light having the first polarization direction of unpolarized light 123 diffused by the light diffusion layer can transmit through the reflective polarizer 150, for example, being reflected by the reflective layer 130 and then passing through the reflective polarizer 150. In this way, the proportion of combined light 124 (including the light P1 having the first polarization direction from the light 122 and the light having the first polarization direction from the light 123) passing through the reflective polarizer 150 can be effectively increased, thereby effectively improving the optical transmission efficiency of the light-emitting structure 100. In addition, in the light-emitting structure 100 of this embodiment, the reflective polarizer 150 is disposed on the encapsulant 140, so the light-emitting structure 100 may be thin and possess a light weight. In one embodiment, the first polarization direction is exemplified as P polarization direction, and the second polarization direction is exemplified as S polarization direction, but this disclosure is not limited thereto.

In this embodiment, the light-emitting structure 100 further includes a reflective frame 170 surrounding the light-emitting chip 120 and surrounding the side surface of the encapsulant 140. The reflective frame 170 may reflect the lateral light 122 emitted by the light-emitting chip 120 to improve the optical transmission efficiency of the light-emitting structure 100.

In this embodiment, the substrate 110 may be a printed circuit board (PCB), a resin substrate, a thin type metal substrate, or a flexible printed circuit board. The reflective polarizer 150 may be constituted by optical materials of multi-layer film stretching stack, or a wire-grid polarizer with periodic microstructure. The reflective layer 130 may be a reflective sheet adhered to the substrate 110, or a reflective coating film coated on the substrate 110. The reflective frame 170 may be a resin frame with high-reflectivity particles or a plastic frame made by injection molding.

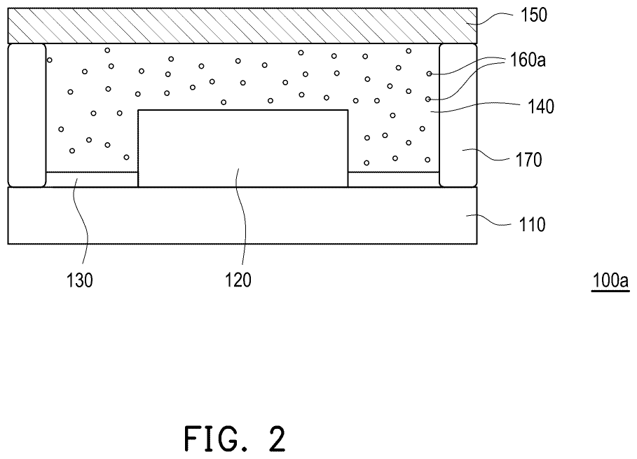

FIG. 2 is a cross-sectional schematic diagram of a light-emitting structure according to another embodiment of this disclosure. Referring to FIG. 2, a light-emitting structure 100a of this embodiment resembles the light-emitting structure 100 of FIG. 1, and the main difference between both is described as follows. In the light-emitting structure 100a of this embodiment, a polarization conversion element 160a is light scattering particles doped in the encapsulant 140. The light scattering particles may diffuse and scatter the light 122, and can disrupt the linear polarization characteristic of the second polarization direction of the light P2 reflected by the reflective polarizer 150, and convert it into no polarization.

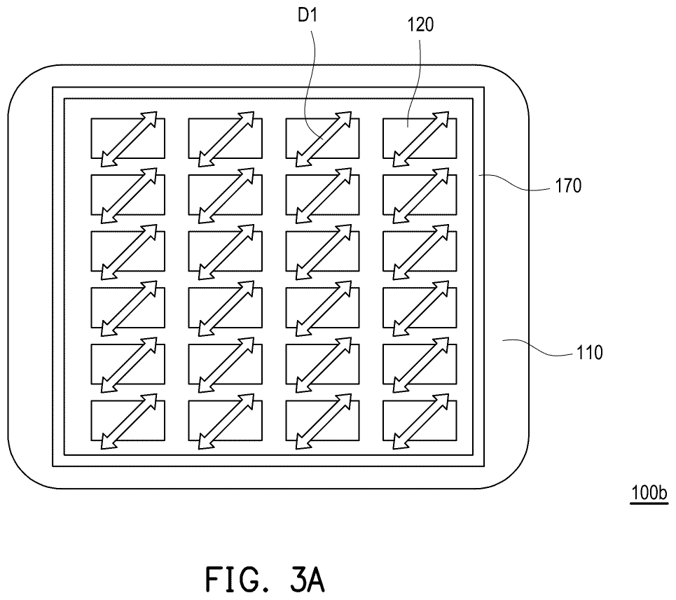

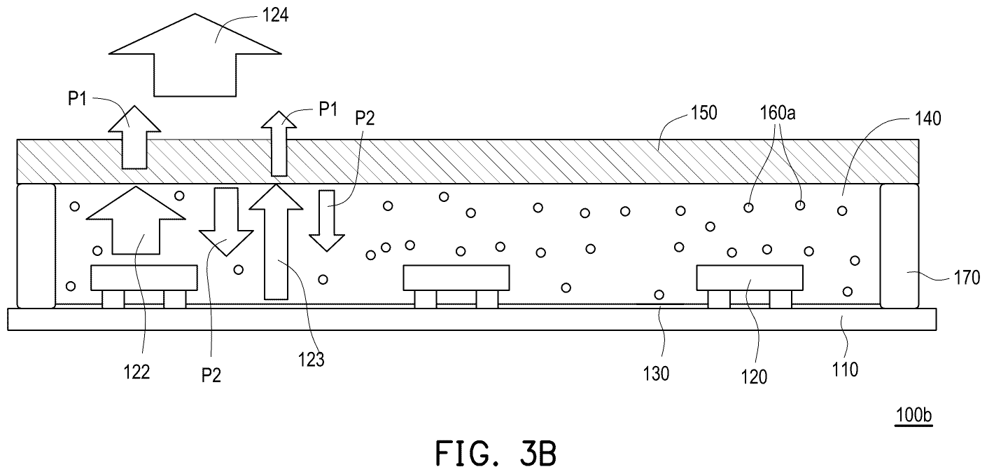

FIG. 3A is a top view schematic diagram of a light-emitting structure according to yet another embodiment of this disclosure, and FIG. 3B is a cross-sectional schematic diagram of the light-emitting structure of FIG. 3A. Referring to FIG. 3A and FIG. 3B, a light-emitting structure 100b of this embodiment resembles the light-emitting structure 100a of FIG. 2, and the main difference between both is described as follows. In the light-emitting structure 100b of this embodiment, the encapsulant 140 covers multiple light-emitting chips 120, and a transmission axis direction D1 of the reflective polarizer 150 is the polarization direction of the combined light 124 having the first polarization direction.

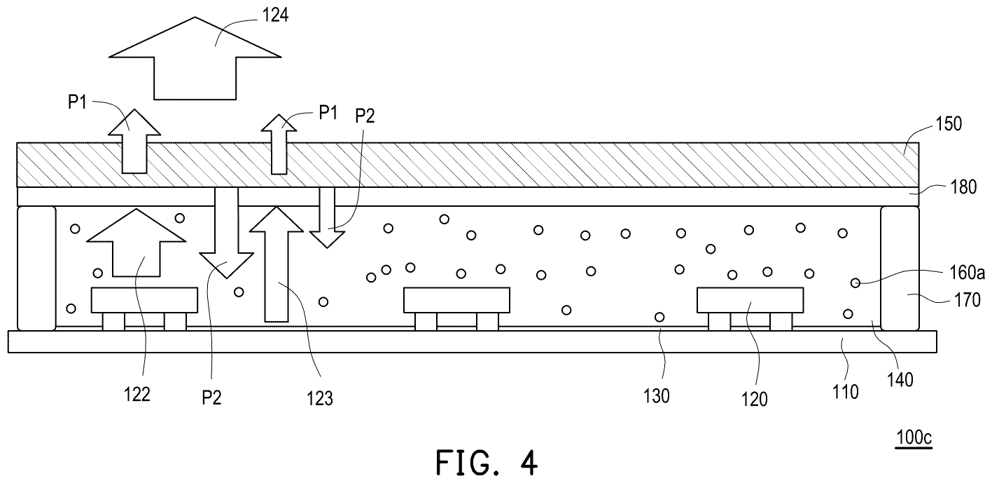

FIG. 4 is a cross-sectional schematic diagram of a light-emitting structure according to still another embodiment of this disclosure. Referring to FIG. 4, a light-emitting structure 100c of this embodiment resembles the light-emitting structure 100b of FIG. 3B, and the main difference between both is described as follows. The light-emitting structure 100c of this embodiment further includes a wavelength conversion layer 180 disposed between the encapsulant 140 and the reflective polarizer 150, and used to modify the wavelength of the light 122. The wavelength conversion layer 180 may be a phosphor layer or a quantum dot layer. For example, in this embodiment, the light-emitting chip 120 may be a blue light emitting diode, and the wavelength conversion layer 180 may be a yellow phosphor layer, to convert the blue light emitted by the blue light emitting diode into yellow light, and the unconverted blue light and yellow light can then be mixed into white light, but this disclosure is not limited thereto. In other embodiments, the light-emitting chip 120 may also emit the light 122 in other wavelength bands, such as visible light in other wavelength bands or ultraviolet light, and the wavelength conversion layer 180 may also be phosphor layers or quantum dot layers of other colors, such as red, green, blue or phosphor layers or quantum dot layers of combinations thereof.

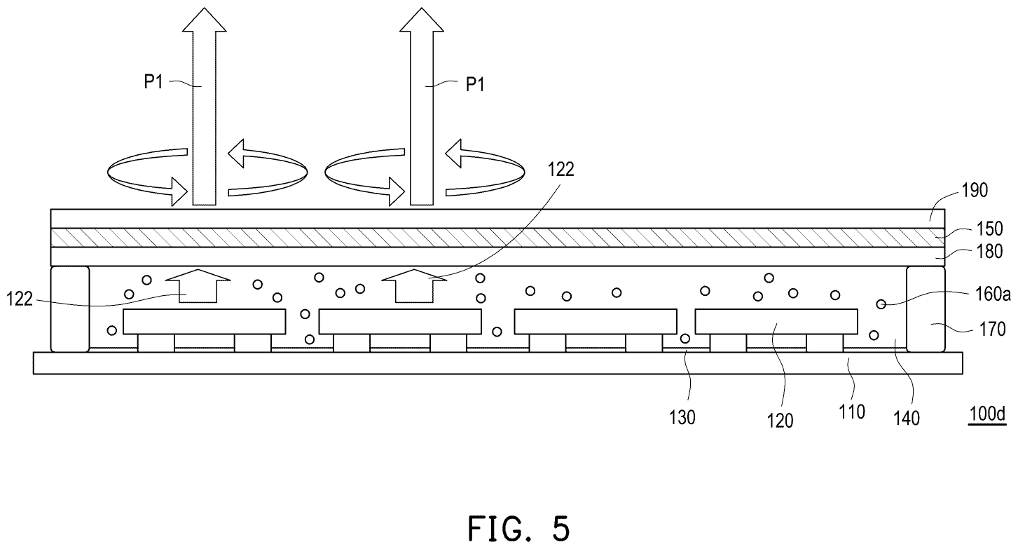

FIG. 5 is a cross-sectional schematic diagram of a light-emitting structure according to another embodiment of this disclosure. Referring to FIG. 5, a light-emitting structure 100d of this embodiment resembles the light-emitting structure 100c of FIG. 4, and the main difference between both is described as follows. The light-emitting structure 100d of this embodiment further includes a wave plate 190, wherein the reflective polarizer 150 is disposed between the encapsulant 140 and the wave plate 190. In one embodiment, the wave plate 190 exemplify a quarter wave plate, which may convert the first polarization direction (i.e., linear polarization) of the light 122 into a circular polarization direction or an elliptical polarization direction, becoming the light P1 with a circular polarization direction or an elliptical polarization direction.

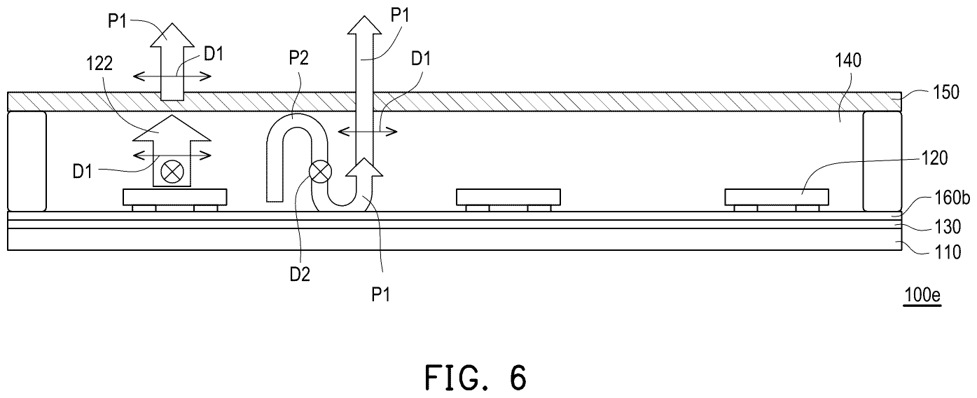

FIG. 6 is a cross-sectional schematic diagram of a light-emitting structure according to yet another embodiment of this disclosure. Referring to FIG. 6, a light-emitting structure 100e of this embodiment resembles the light-emitting structure 100b of FIG. 3B, and the main difference between both is described as follows. In the light-emitting structure 100e of this embodiment, a polarization conversion element 160b is a wave plate disposed between the reflective layer 130 and the encapsulant 140. In one embodiment, the polarization conversion element 160b exemplify a quarter wave plate the light P2 of the light 122 that is reflected by the reflective polarizer 150 and possesses a second polarization direction D2 will sequentially pass through this quarter wave plate, be reflected by the reflective layer 130, and pass through this quarter wave plate again, and because the light P2 of the light 122 passes through the quarter wave plate twice, its polarization direction will be converted from the second polarization direction D2 to the first polarization direction D1, thereby enabling the light P2 of the light 122, after passing through the quarter wave plate twice, to be converted into the light P1 having the first polarization direction D1 and continue to pass through the reflective polarizer 150 to become reusable and effective light.

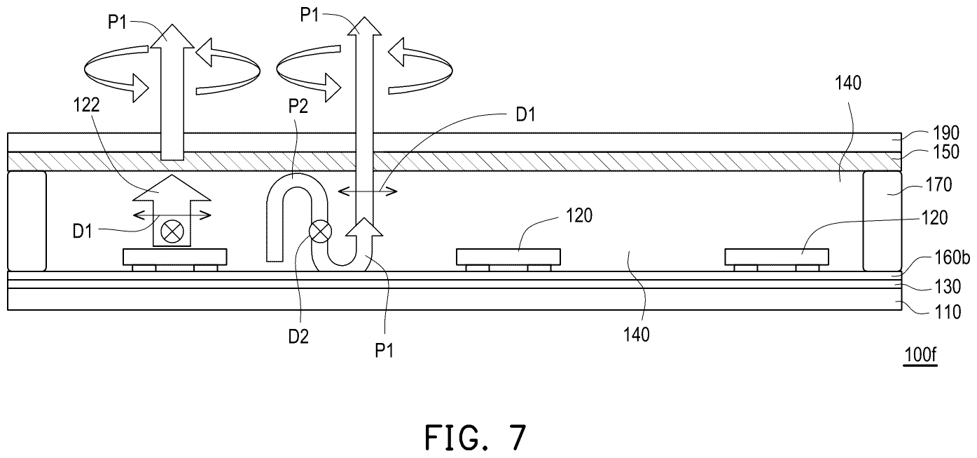

FIG. 7 is a cross-sectional schematic diagram of a light-emitting structure according to still another embodiment of this disclosure. Referring to FIG. 7, a light-emitting structure 100f of this embodiment resembles the light-emitting structure 100e of FIG. 6, and the main difference between both lies in that the light-emitting structure 100f of this embodiment further includes a wave plate 190, wherein the reflective polarizer 150 is disposed between the encapsulant 140 and the wave plate 190. In one embodiment, the wave plate 190 exemplify a quarter wave plate, which may convert the first polarization direction (i.e., linear polarization) of the light 122 into a circular polarization direction.

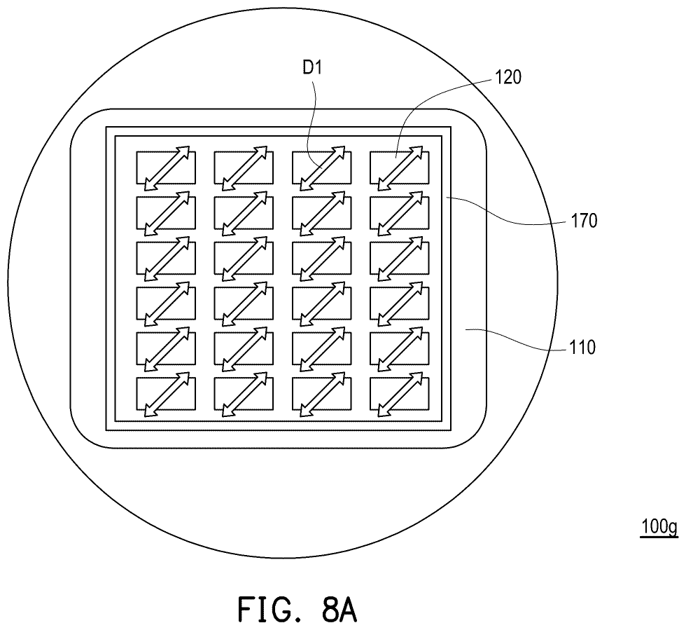

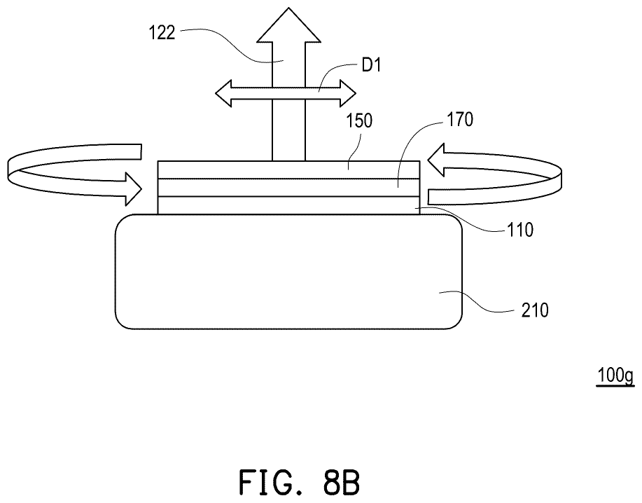

FIG. 8A is a top view schematic diagram of a light-emitting structure according to another embodiment of this disclosure, and FIG. 8B is a side view schematic diagram of the light-emitting structure of FIG. 8A. Referring to FIG. 8A and FIG. 8B, a light-emitting structure 100g of this embodiment resembles the light-emitting structure 100b of FIG. 3A and FIG. 3B, and the main difference between both lies in that the light-emitting structure 100g of this embodiment further includes a motor base 210, wherein the substrate 110 is disposed on the motor base 210, the motor base 210 is used to rotate the substrate 110, thereby rotating the reflective polarizer 150. Specifically, the motor base 210 may rotate with the optical axis of the reflective polarizer 150 as the axis, thereby rotating the first polarization direction D1. As such, the light-emitting structure 100g may be applied in more scenarios, providing the light 122 with appropriate polarization direction.

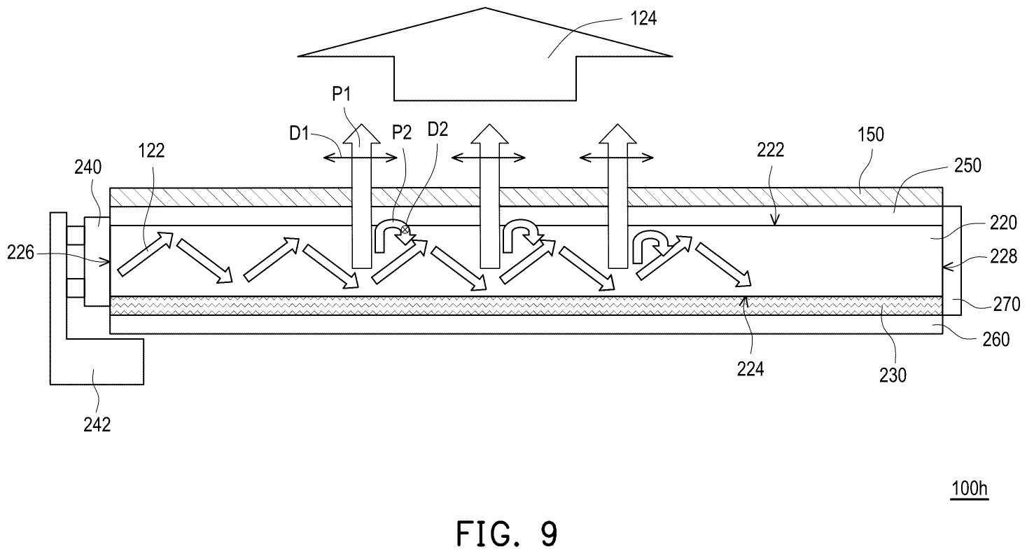

FIG. 9 is a cross-sectional schematic diagram of a light-emitting structure according to yet another embodiment of this disclosure. Referring to FIG. 9, a light-emitting structure 100h of this embodiment includes a light guide plate 220, at least one light-emitting element 240, a light-transmitting layer 250, a reflective polarizer 150, and a first reflective layer 260. The light guide plate 220 possesses a first surface 222, a second surface 224 opposite to the first surface 222, and at least one light incident surface 226 connecting the first surface 222 and the second surface 224, wherein the second surface 224 is equipped with a light scattering microstructure layer 230. At least one light-emitting element 240 is disposed on the at least one light incident surface 226, and emits light towards the at least one light incident surface 226. The light-transmitting layer 250 is disposed on the first surface 222, wherein the refractive index of the light-transmitting layer 250 falls below the refractive index of the light guide plate 220. The light-transmitting layer 250 is disposed between the light guide plate 220 and the reflective polarizer 150. The first reflective layer 260 is disposed on the second surface 224.

In this embodiment, the light 122 emitted from the light-emitting element 240 enters the light guide plate 220 through the light incident surface 226. Since the refractive index of the light-transmitting layer 250 falls below the refractive index of the light guide plate 220, when the light 122 shoots at the first surface 222 at an incident angle greater than the critical angle, it will be totally reflected by the first surface 222 and confined within the light guide plate 220. Similarly, when the light 122 shoots at the second surface 224 at an incident angle greater than the critical angle, it will also be totally reflected by the second surface 224 and confined within the light guide plate 220. As such, the light 122 can be transmitted within the light guide plate 220 towards a side surface 228 of the light guide plate 220 opposite to the light incident surface 226. However, when the light 122 shoots at the second surface 224 and the microstructures of the light scattering microstructure layer 230 on the second surface 224, the microstructures will disrupt the total reflection, causing the light 122 to scatter. As such, a portion of the light 122 may be scattered upward and pass through the light-transmitting layer 250 to be transmitted the reflective polarizer 150, while another portion of the light 122 is scattered downward and then reflected upward by the first reflective layer 260, and sequentially passes through the light guide plate 220 and the light-transmitting layer 250 to be transmitted to the reflective polarizer 150. For the light scattered by the light scattering microstructure layer 230, the reflective polarizer 150 works like it described in the embodiment of FIG. 1, which is used to allow the light P1 having the first polarization direction D1 of the scattered light to pass through, and to reflect the light P2 having the second polarization direction D2 of the scattered light. The polarization direction of light P2 reflected by the reflective polarizer 150 may be modified by scattering of the light scattering microstructure layer 230 to become the unpolarized light, and the light P1 having the first polarization direction D1 therein may pass through the reflective polarizer 150, thereby increasing the proportion of the combined light 124 of the light 122 that passes through the reflective polarizer 150. Therefore, the light-emitting structure 100h of this embodiment may possess higher optical transmission efficiency.

In addition, in the light-emitting structure 100h of this embodiment, the architecture adopts the reflective polarizer 150 disposed above the first surface 222 of the light guide plate 220, therefore the light-emitting structure 100h may be thin and possess relatively light weight.

In this embodiment, the light-emitting structure 100h further includes a second reflective layer 270, wherein the light guide plate 220 possesses a side surface 228 opposite to the light incident surface 226, and connecting the first surface 222 and the second surface 224, and the second reflective layer 270 is disposed on the side surface 228 to reflect the light 122 transmitted laterally within the light guide plate 220, so that the light 122 may be recycled and reused, thereby increasing the optical transmission efficiency of the light-emitting structure 100h. In one embodiment, reflective layers may also be equipped on the other two side surfaces adjacent to the light incident surface 226 and connecting the light incident surface 226 and the side surface 228, to further increasing the recycling rate of the light 122, or in another embodiment, no reflective layers may be equipped on these other two side surfaces.

In this embodiment, the material of the light guide plate 220 may be plastic or glass, such as polymethyl methacrylate or optical glass. The first reflective layer 260 and the second reflective layer 270 may be reflective films or reflective coatings. In this embodiment, the light-emitting element 240 may include the light-emitting chip 120 as shown in FIG. 1, which may be electrically connected to the flexible printed circuit board and a driving circuit 242. In addition, the light-emitting element 240 may be a light-emitting diode that can emit white light, or may include multiple light-emitting diodes with different light-emitting colors (such as blue light, green light and, red light light-emitting diodes), or may be a light-emitting diode that emits a single color of light (such as any one of blue light light-emitting diode, green light light-emitting diode, and red light light-emitting diode).

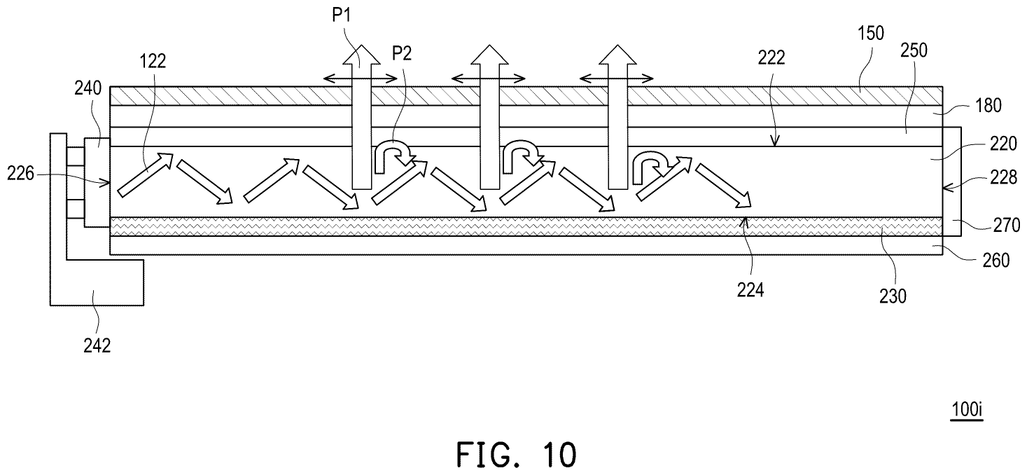

FIG. 10 is a cross-sectional schematic diagram of a light-emitting structure according to still another embodiment of this disclosure. Referring to FIG. 10, a light-emitting structure 100i of this embodiment resembles the light-emitting structure 100h of FIG. 9, and the main difference between both lies in that the light-emitting structure 100i of this embodiment further includes a wavelength conversion layer 180 disposed between the light-transmitting layer 250 and the reflective polarizer 150. The wavelength conversion layer 180 may be a phosphor layer or a quantum dot layer. For example, in this embodiment, the light-emitting element 240 may be a blue light emitting diode, and the wavelength conversion layer 180 may be a yellow phosphor layer, to convert the blue light emitted from the blue light emitting diode into yellow light, and the unconverted blue light and yellow light can then be mixed into white light, but this disclosure is not limited to this. In other embodiments, the light-emitting element 240 may also emit the light 122 in other wavelength bands, such as visible light in other wavelength bands or ultraviolet light, and the wavelength conversion layer 180 may also be a phosphor layer or quantum dot layer of other colors, such as a phosphor layer or quantum dot layer of red, green, blue or combinations thereof.

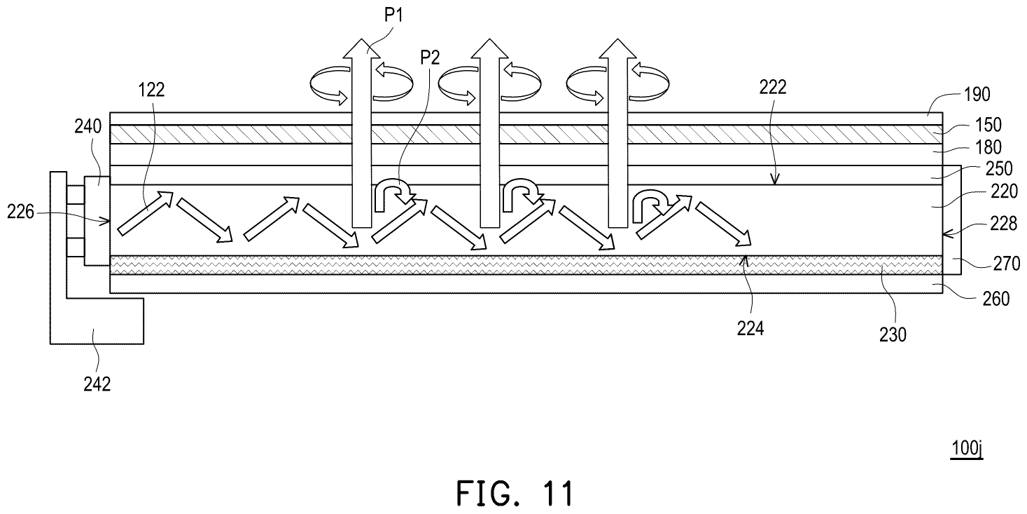

FIG. 11 is a cross-sectional schematic diagram of a light-emitting structure according to another embodiment of this disclosure. Referring to FIG. 11, a light-emitting structure 100j of this embodiment resembles the light-emitting structure 100i of FIG. 10, and the main difference between both lies in that the light-emitting structure 100j of this embodiment further includes a wave plate 190, wherein the reflective polarizer 150 is disposed between the light-transmitting layer 250 and the wave plate 190. In one embodiment, the wave plate 190 exemplify a quarter-wave plate, which may convert the first polarization direction (i.e., linear polarization) of the light 122 into a circular polarization direction or an elliptical polarization direction.

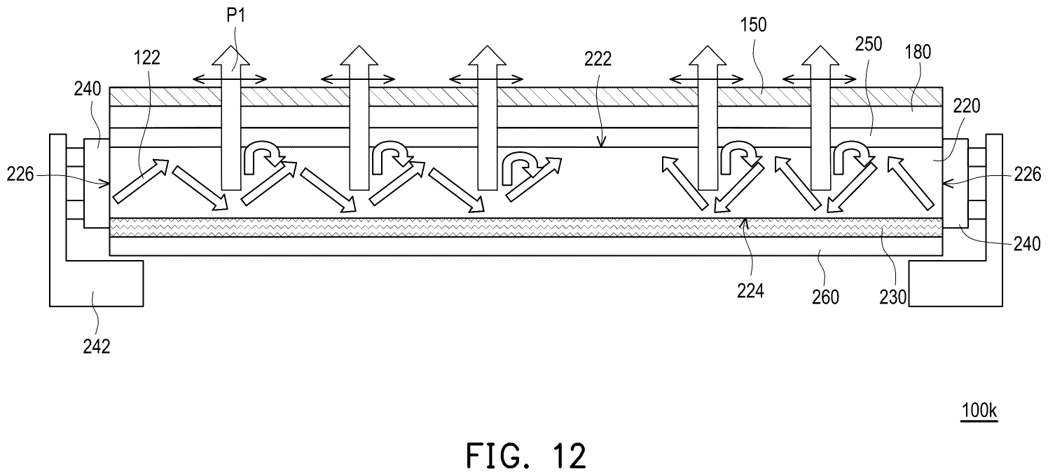

FIG. 12 is a cross-sectional schematic diagram of a light-emitting structure according to yet another embodiment of this disclosure. Referring to FIG. 12, a light-emitting structure 100k of this embodiment resembles the light-emitting structure 100i of FIG. 10, and the main difference between both lies in that the light guide plate 220 of the light-emitting structure 100i of FIG. 10 has only one light incident surface 226, while the light guide plate 220 of the light-emitting structure 100k of this embodiment has two opposite light incident surfaces 226, and two light-emitting elements 240 are disposed next to these two opposite light incident surfaces 226 respectively. This may increase the amount of the light P1 provided by the light-emitting structure 100k. In other embodiments, it may also be that three or four side surfaces of the light guide plate 220 are all light incident surfaces 226, and each light incident surface 226 is equipped with a light-emitting element 240.

In summary, in the light-emitting structure of the embodiment of this disclosure, a reflective polarizer is utilized to transmit the light having a first polarization direction from the light emitted by the light-emitting chip, and reflect the light having a second polarization direction from this light, and a polarization conversion element is adopted to modify the polarization direction of the light reflected by the reflective polarizer, so that more light possesses the first polarization direction and may pass through the reflective polarizer. Therefore, the light-emitting structure of the embodiment of this disclosure may possess higher optical transmission efficiency. In addition, in the light-emitting structure of the embodiment of this disclosure, the reflective polarizer is disposed on the encapsulant, thus the light-emitting structure may be thin and possess light weight. In the light-emitting structure of the embodiment of this disclosure, the light-transmitting layer is configured on the first surface of the light guide plate, the light-transmitting layer is disposed between the light guide plate and the reflective polarizer, and the second surface of the light guide plate is equipped with a light scattering microstructure layer, therefore the polarization direction of the light reflected by the reflective polarizer may be modified through the light being scattered by the light scattering microstructure layer, thereby increasing the proportion of light passing through the reflective polarizer. Therefore, the light-emitting structure of the embodiment of this disclosure may possess higher optical efficiency. Additionally, in the light-emitting structure of the embodiment of this disclosure, an architecture where the reflective polarizer is disposed above the first surface of the light guide plate is adopted, thus the light-emitting structure may be thin and possess light weight.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light-emitting structure, comprising:
a substrate;
at least one light-emitting chip, disposed on the substrate;
a reflective layer, disposed on the substrate;
an encapsulant, encapsulating the light-emitting chip, and covering the reflective layer;
a reflective polarizer, disposed on the encapsulant; and
a polarization conversion element, disposed on the encapsulant or within the encapsulant, wherein the reflective polarizer is configured to transmit light having a first polarization direction from light emitted by the light-emitting chip, and to reflect light having a second polarization direction from the light, and the polarization conversion element is configured to modify the polarization direction of the light reflected by the reflective polarizer.

2. The light-emitting structure according to claim 1, wherein the polarization conversion element is a light diffusion layer, disposed between the encapsulant and the reflective polarizer.

3. The light-emitting structure according to claim 1, wherein the polarization conversion element is light scattering particles doped in the encapsulant.

4. The light-emitting structure according to claim 1, wherein the light-emitting structure further comprises a reflective frame surrounding the light-emitting chip and surrounding a side surface of the encapsulant.

5. The light-emitting structure according to claim 1, wherein the light-emitting structure further comprises a wavelength conversion layer, disposed between the encapsulant and the reflective polarizer, and configured to modify a wavelength of the light.

6. The light-emitting structure according to claim 1, wherein the light-emitting structure further comprises a wave plate, wherein the reflective polarizer is disposed between the encapsulant and the wave plate.

7. The light-emitting structure according to claim 1, wherein the polarization conversion element is a wave plate disposed between the reflective layer and the encapsulant.

8. The light-emitting structure according to claim 7, wherein the wave plate is a quarter wave plate.

9. The light-emitting structure according to claim 1, wherein the light-emitting structure comprises a motor base, wherein the substrate is disposed on the motor base, the motor base is configured to rotate the substrate, thereby rotating the reflective polarizer.

10. A light-emitting structure, comprising:
a light guide plate, having a first surface, a second surface opposite to the first surface, and at least one light incident surface connecting the first surface and the second surface, wherein the second surface is equipped with a light scattering microstructure layer;
at least one light-emitting element, disposed next to the at least one light incident surface, and emitting light towards the at least one light incident surface;
a light-transmitting layer, disposed at the first surface, wherein a refractive index of the light-transmitting layer falls below a refractive index of the light guide plate;
a reflective polarizer, wherein the light-transmitting layer is disposed between the light guide plate and the reflective polarizer; and
a first reflective layer, disposed on the second surface.

11. The light-emitting structure according to claim 10, wherein the light-emitting structure further comprises a second reflective layer, wherein the light guide plate has a side surface opposite to the light incident surface and connecting the first surface and the second surface, and the second reflective layer is disposed on the side surface.

12. The light-emitting structure according to claim 10, wherein the light-emitting structure further comprises a wavelength conversion layer, disposed between the light-transmitting layer and the reflective polarizer.

13. The light-emitting structure according to claim 10, wherein the light-emitting structure further comprises a wave plate, wherein the reflective polarizer is disposed between the light-transmitting layer and the wave plate.
